(19) United States
(12) Patent Application Publication
(10) Pub. No.: US 2009/0121122 A1
(43) Pub. Date: May 14, 2009

(54) TECHNIQUES FOR MEASURING AND CONTROLLING ION BEAM ANGLE AND DENSITY UNIFORMITY

(75) Inventors: Peter L. Kellerman, Essex, MA (US); Kenneth Purser, Lexington, MA (US); Svetlana Radovanov, Marblehead, MA (US); Victor M. Benveniste, Lyle, WA (US); Frank Sinclair, Quincy, MA (US); John Slocum, Medford, MA (US)

Correspondence Address: HUNTON & WILLIAMS LLP/VARIAN SEMICONDUCTOR,;EQUIPMENT ASSOCIATES, INC., INTELLECTUAL PROPERTY DEPARTMENT, 1900 K STREET, N.W., SUITE 1200, WASHINGTON, DC, 20006-1109, US

(73) Assignee: Varian Semiconductor Equipment Associates, Inc., Gloucester, MA (US)

(21) Appl. No.: 11/939,173

(22) Filed: Nov. 13, 2007

(51) Int. Cl. H01J 37/08; G01D 18/00

(52) U.S. Cl. 250/252.1; 250/492.21

(57) ABSTRACT

Techniques for measuring and controlling ion beam angle and density uniformity are disclosed. In one particular exemplary embodiment, the techniques may be realized as an apparatus for measuring and controlling ion beam angle and density uniformity. The apparatus may include a measuring assembly having an opening, a cup, and at least one collector at the rear of the cup. The apparatus may further include an actuator to move the measuring assembly along an actuation path to scan an ion beam to measure and control ion beam uniformity.

### FIELD OF THE DISCLOSURE

The present disclosure relates generally to plasma-based ion implantation and, more particularly, to techniques for measuring and controlling ion beam angle and density uniformity.

### BACKGROUND OF THE DISCLOSURE

Ion implanters are widely used in semiconductor manufacturing to selectively alter conductivity of materials. In a typical ion implanter, ions generated from an ion source are directed through a series of beam-line components which include one or more analyzing magnets and a plurality of electrodes. The analyzing magnets select desired ion species, filter out contaminant species and ions having undesirable energies, and adjust ion beam quality at a target wafer. Suitably shaped electrodes may modify the energy and the shape of an ion beam.

In production, semiconductor wafers are typically scanned with an ion beam. As used hereinafter, “scanning” of an ion beam refers to the relative movement of an ion beam with respect to a wafer or substrate surface.

An ion beam is typically either a “spot beam” having an approximately circular or elliptical cross section or a “ribbon beam” having a rectangular cross section. For the purpose of the present disclosure, a “ribbon beam” may refer to either a static ribbon beam or a scanned ribbon beam. The latter type of ribbon beam may be created by scanning a spot beam back and forth at a high frequency.

In the case of a spot beam, scanning of a wafer may be achieved by sweeping the spot beam back and forth between two endpoints to form a beam path and by simultaneously moving the wafer across the beam path. Alternatively, the spot beam may be kept stationary, and the wafer may be moved in a two-dimensional (2-D) pattern with respect to the spot beam. In the case of a ribbon beam, scanning of a wafer may be achieved by keeping the ribbon beam stationary and by simultaneously moving the wafer across the ribbon beam. If the ribbon beam is wider than the wafer, a one-dimensional (1-D) movement of the wafer may cause the ribbon beam to cover the entire wafer surface. The much simpler 1-D scanning makes a ribbon beam a desired choice for single-wafer ion implantation production.

However, just like spot beams, ribbon beams can suffer from intrinsic non-uniformity problems. A ribbon beam typically consists of a plurality of beamlets, wherein each beamlet may be considered, conceptually, as one spot beam. Although beamlets within a ribbon beam travel in the same general direction, any two beamlets may not be pointing in exactly the same direction. In addition, each beamlet may have an intrinsic angle spread. As a result, during ion implantation with a ribbon beam, different locations on a target wafer may experience different ion incident angles. Furthermore, the beamlets may not be evenly spaced within the ribbon beam. One portion of the ribbon beam where beamlets are densely distributed may deliver a higher ion dose than another portion of the ribbon beam where beamlets are sparsely distributed. Therefore, a ribbon beam may lack angle uniformity and/or dose uniformity.

Ion beam angle uniformity and/or dose uniformity may be controlled by several ion implantation components. For example, electric and/or magnetic elements may be utilized.

FIG. 1 shows a conventional ion implanter 100 comprising an ion source 102, extraction electrodes 104, a 90° magnet analyzer 106, a first deceleration (D1) stage 108, a 700 magnet analyzer 110, and a second deceleration (D2) stage 112. The D1 and D2 deceleration stages (also known as “deceleration lenses”) each comprising multiple electrodes with a defined aperture to allow an ion beam to pass therethrough. By applying different combinations of voltage potentials to the multiple electrodes, the D1 and D2 deceleration lenses may manipulate ion energies and cause the ion beam to hit a target wafer at a desired energy.

The above-mentioned D1 or D2 deceleration lenses are typically electrostatic triode (or tetrode) deceleration lenses. FIG. 2 shows a perspective view of a conventional electrostatic triode deceleration lens 200. The electrostatic triode deceleration lens 200 comprises three sets of electrodes: entrance electrodes 202 (also referred to as “terminal electrodes”), suppression electrodes 204 (or “focusing electrodes”), and exit electrodes 206 (also referred to as “ground electrodes” though not necessarily connected to earth ground). A conventional electrostatic tetrode deceleration lens is similar to the electrostatic triode deceleration lens 200, except that a tetrode lens has an additional set of suppression electrodes (or focusing electrodes) between the suppression electrodes 204 and the exit electrodes 206.

In the electrostatic triode deceleration lens 200, each set of electrodes may have a space to allow an ion beam 20 to pass therethrough (e.g., in the +z direction along the beam direction). As shown in FIG. 2, each set of electrodes may include two conductive pieces, which may be electrically coupled to each other to share a common voltage potential. Alternatively, each set of electrodes may be a one-piece structure with an aperture for the ion beam 20 to pass therethrough. As such, each set of electrodes are effectively a single electrode having a single voltage potential. For simplicity, each set of electrodes is referred to in singular. That is, the entrance electrodes 202 are referred to as an “entrance electrode 202,” the suppression electrodes 204 are referred to as a “suppression electrode 204,” and the exit electrodes 206 are referred to as an “exit electrode 206.”

In operation, the entrance electrode 202, the suppression electrode 204, and the exit electrode 206 are independently biased such that the energy of the ion beam 20 is manipulated in the following fashion. The ion beam 20 may enter the electrostatic triode deceleration lens 200 through the entrance electrode 202 and may have an initial energy of, for example, 10-20 keV. Ions in the ion beam 20 may be accelerated between the entrance electrode 202 and the suppression electrode 204. Upon reaching the suppression electrode 204, the ion beam 20 may have an energy of, for example, approximately 30 keV or higher. Between the suppression electrode 204 and the exit electrode 206, the ions in the ion beam 20 may be decelerated, typically to an energy that is closer to one used for ion implantation of a target wafer. For example, the ion beam 20 may have an energy of approximately 3-5 keV or lower when it exits the electrostatic triode deceleration lens 200.

Significant changes in ion energies that take place in the electrostatic triode deceleration lens 200 can have a substantial impact on a shape of the ion beam 20. FIG. 3 shows a top view of the electrostatic triode deceleration lens 200. As is well known, space charge effects are more significant in low-energy ion beams than in high-energy ion beams. Therefore, as the ion beam 20 is accelerated between the entrance electrode 202 and the suppression electrode 204, little change is observed in the shape of the ion beam 20. However, when the ion energy is reduced between the suppression electrode 204 and the exit electrode 206, the ion beam 20 tends to expand in both X and Y dimensions at its edges. As a result, a considerable number of ions may be lost before they reach the target wafer, and the effective dose and angle uniformity of the ion beam 20 may be reduced.

There have been attempts to reduce the above-described space charge effect in an electrostatic triode lens. For example, tuning the voltages of the deceleration lenses may help reduce space charge effect. However, because forces associated with the space charge effect may be highly non-linear (especially if the beam is not elliptical), tuning the voltages of the deceleration lenses may be very challenging without accurate tuning assistance to compensate for the space charge effect.

Another approach to improve ion beam angle and/or dose uniformity may include introducing one or more magnetic elements. FIG. 4 depicts a common geometry 400 for implanting ions onto a target wafer. A ribbon beam 40, which typically exits from a mass selection slit (not shown), enters a magnetic deflector 401 at an entrance region. The magnetic deflector 401 deflects the incoming ribbon beam 40 to provide a mass-analyzed beam suitable for implantation of a target wafer 403 at an implantation station 402. In this specific geometry 400, a corrector-bar pair 404 may be introduced at the entrance and/or exit regions of the magnetic deflector 401 to improve uniformity across the target wafer 403.

Referring to FIG. 5, the corrector-bar pair 404 includes a pair of horizontal magnetic core members, such as an upper steel bar 502 and a lower steel bar 504, that form a gap or space 506 to allow a ribbon beam 50 to pass therethrough. The corrector-bar pair 404 provides a magnetic supporting structure needed for producing desired deflection fields. A plurality of coils 508 may be wound along the upper steel bar 502 and the lower steal bar 504. Each coil 508 may be individually and/or independently excited with a current, so as to generate high-order multipole components without dedicated windings. Individual excitation of each coil 508, or each multipole, may deflect one or more beamlets within the ribbon beam 50. That is, local variations in ion density or shape of the ribbon beam 50 may be corrected by modifying the magnetic fields locally. These corrections may be made under computer control and on a time scale that is only limited by a decay rate of eddy currents in the horizontal magnetic core members 502, 504.

Although these additional electric and/or magnetic components have been utilized in conventional ion implanters to somewhat improve either angle uniformity and/or dose uniformity of an ion beam, a more efficient solution has yet to be made available for providing ion beams that meet current dose and angle uniformity requirements for ion implantation production. For example, it is typically required that a ribbon beam should produce, in a wafer plane, a dose uniformity with less than 1% variations together with an angle uniformity with less than 0.50 variations. Such stringent uniformity requirements are becoming more difficult to meet since both types of uniformity may be elusive, especially in semiconductor manufacturing which require relatively high specificity and reliability.

In view of the foregoing, it may be understood that there are significant problems and shortcomings associated with current ion implantation technologies.

### SUMMARY OF THE DISCLOSURE

Techniques for measuring and controlling ion beam angle and density uniformity are disclosed. In accordance with one particular exemplary embodiment, the techniques may be realized as an apparatus for measuring and controlling ion beam angle and density uniformity. The apparatus may include a measuring assembly having an opening, a cup, and at least one collector at the rear of the cup. The apparatus may further include an actuator to move the measuring assembly along an actuation path to scan an ion beam to measure and control ion beam uniformity.

In accordance with other aspects of this particular exemplary embodiment, the ion beam uniformity may include at least one of angle uniformity and dose uniformity.

In accordance with further aspects of this particular exemplary embodiment, the measuring assembly may include a scanning high resolution angle profiler or a slit faraday cup.

In accordance with additional aspects of this particular exemplary embodiment, the opening may be a slit having a width of equal to or less than 1 inch.

In accordance with other aspects of this particular exemplary embodiment, the at least one collector may have a width that is equal to or less than the width of the opening.

In accordance with further aspects of this particular exemplary embodiment, the actuator may include one of a single straight linear actuator, a pivoting actuator, a curved rail actuator, or a combination thereof.

In accordance with additional aspects of this particular exemplary embodiment, the actuation path may be at least one of a curved actuation path and a straight actuation path.

In accordance with other aspects of this particular exemplary embodiment, the measuring assembly is rotatable about an axis at a point where the measuring assembly is connected to the actuator.

In accordance with further aspects of this particular exemplary embodiment, the apparatus may further include a differential amplifier coupled to the at least one collector of the measuring assembly, such that the differential amplifier determines ion beam uniformity based on ion beam measurements by the at least one collector.

In accordance with additional aspects of this particular exemplary embodiment, the apparatus may further include one or more tuning elements for tuning ion beam uniformity, such that the one or more tuning elements may be at least one of electrostatic tuning elements and magnetic tuning elements.

In accordance with another particular exemplary embodiment, the techniques may be realized as a method for providing ion beam uniformity. The method may comprise tuning a first tuning element, based on a first set of ion beam information collected at a measuring assembly, to provide dose uniformity at a second tuning element, downstream from the first tuning element. The method may also comprise tuning the second tuning element, based on a second set of ion beam information collected at the measuring assembly, to provide dose and angle uniformity at a wafer.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 depicts a conventional ion implanter system.

FIGS. 2-3 depict conventional electrostatic lens configurations.

FIG. 4 depicts a conventional magnetic deflector configuration.

FIG. 5 depicts a conventional corrector-bar pair configuration.

FIG. 6 depicts a scanning high resolution angle profiler (SHRAP) according to an embodiment of the present disclosure.

FIG. 7 depicts an electrostatic lens configuration using a scanning high resolution angle profiler (SHRAP) according to an embodiment of the present disclosure.

FIGS. 8A-8B depict exemplary screenshots of measurements using scanning high resolution angle profiler (SHRAP) according to an embodiment of the present disclosure.

FIGS. 9A-9C depict exemplary actuation configurations for a scanning high resolution angle profiler (SHRAP) according to an embodiment of the present disclosure.

FIG. 10A-10B depict exemplary tuning configurations using a scanning high resolution angle profiler (SHRAP) according to an embodiment of the present disclosure.

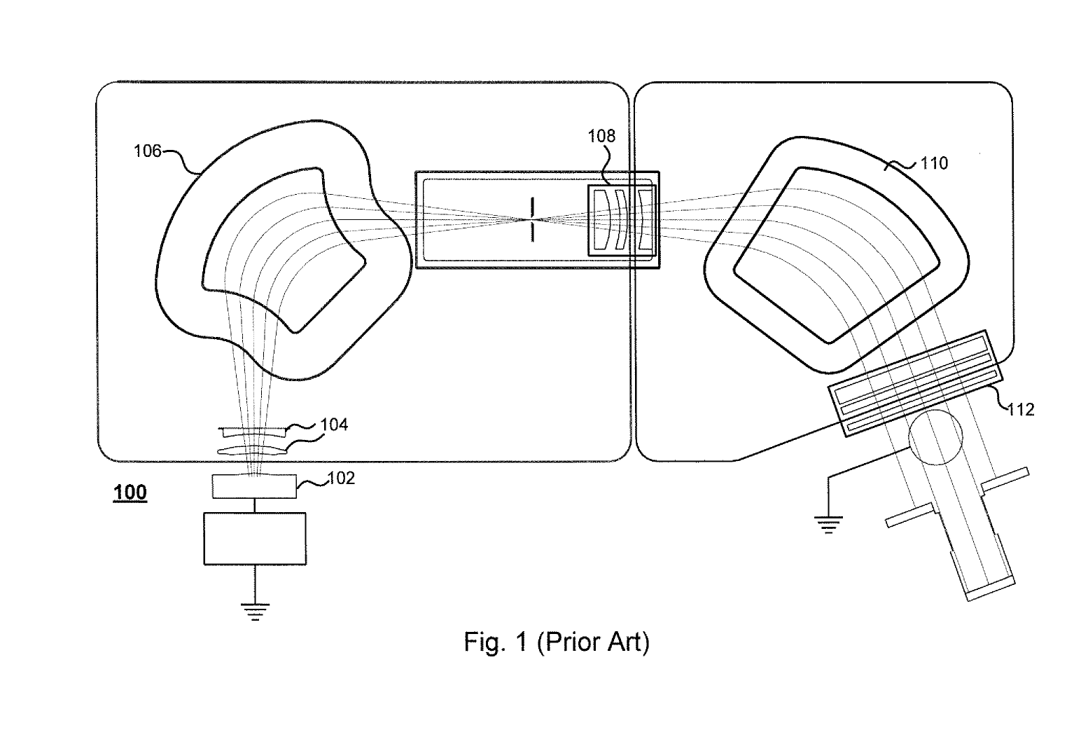

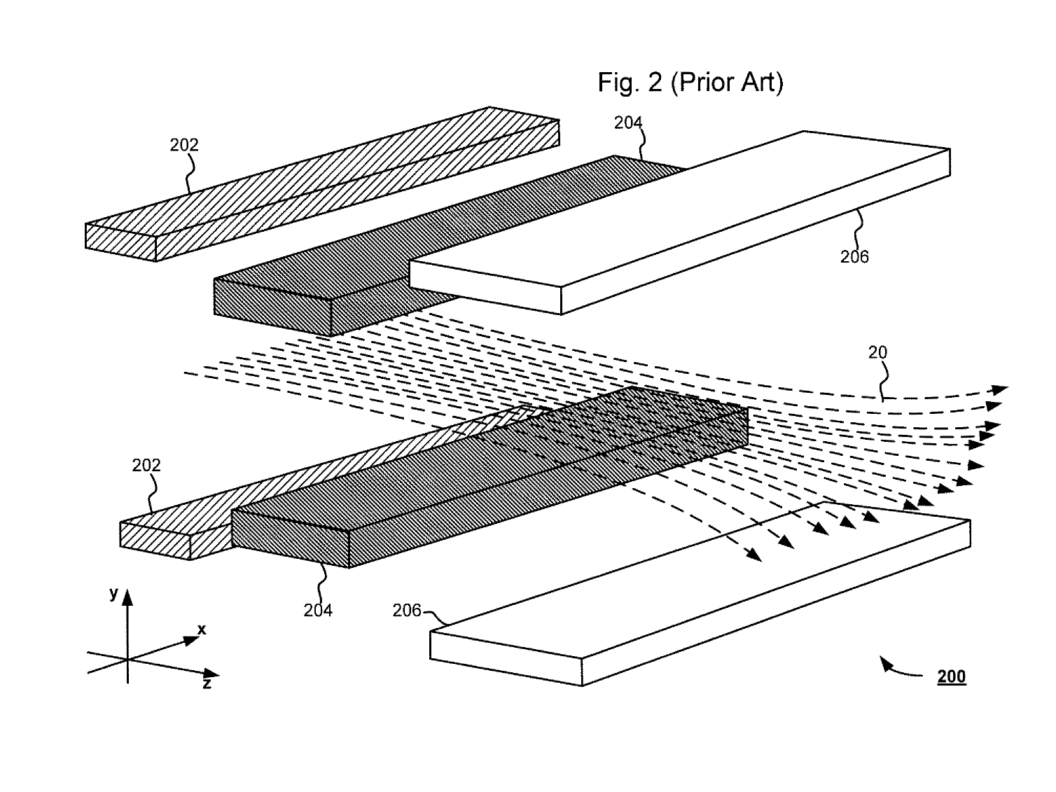

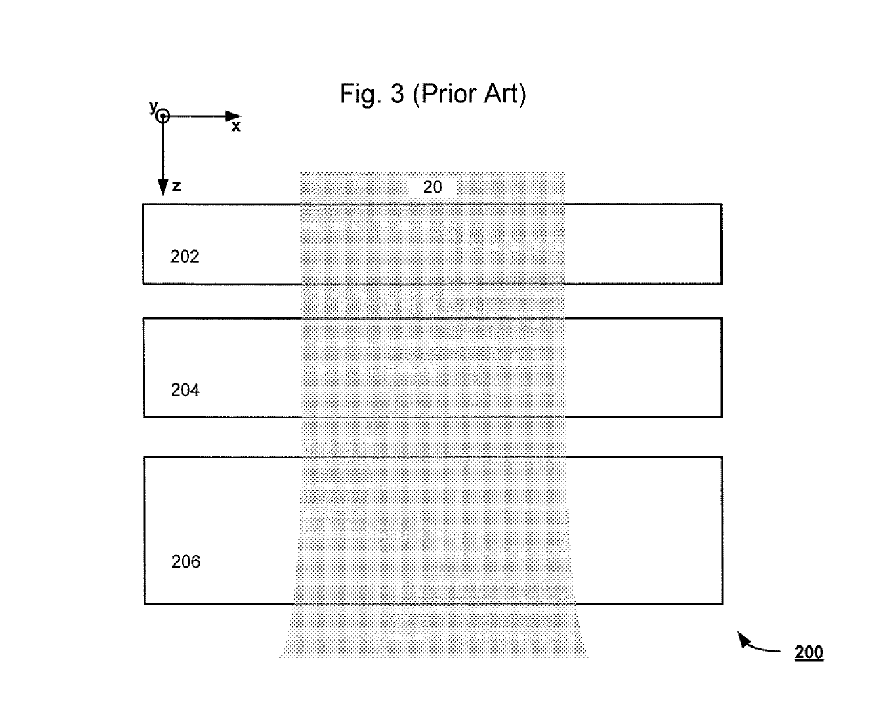

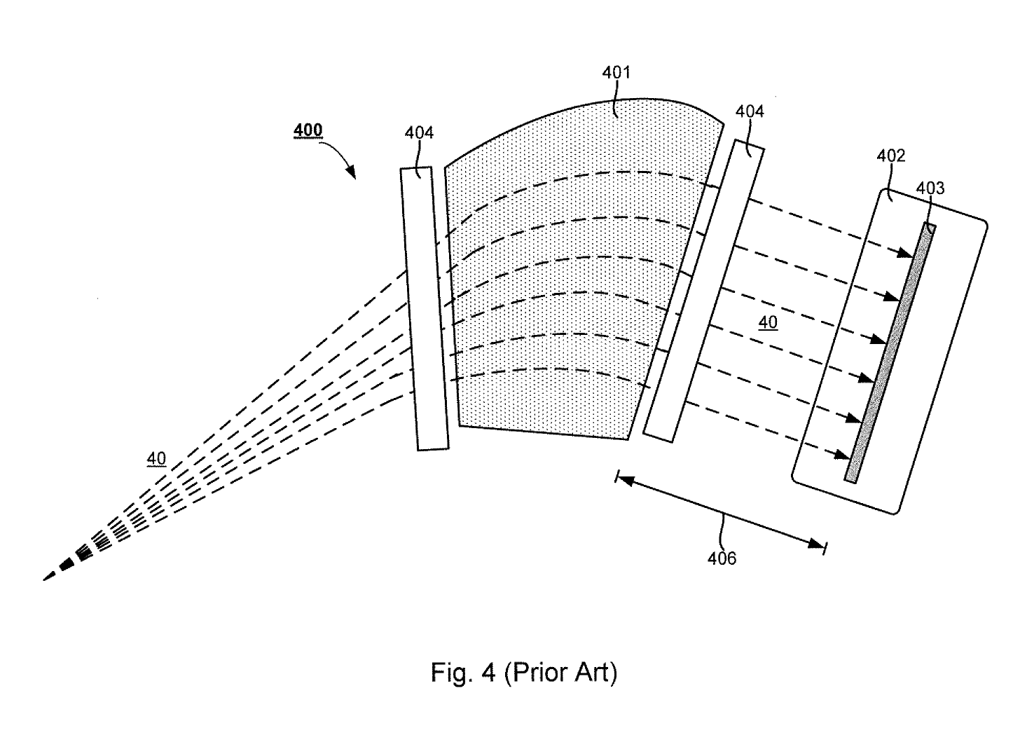

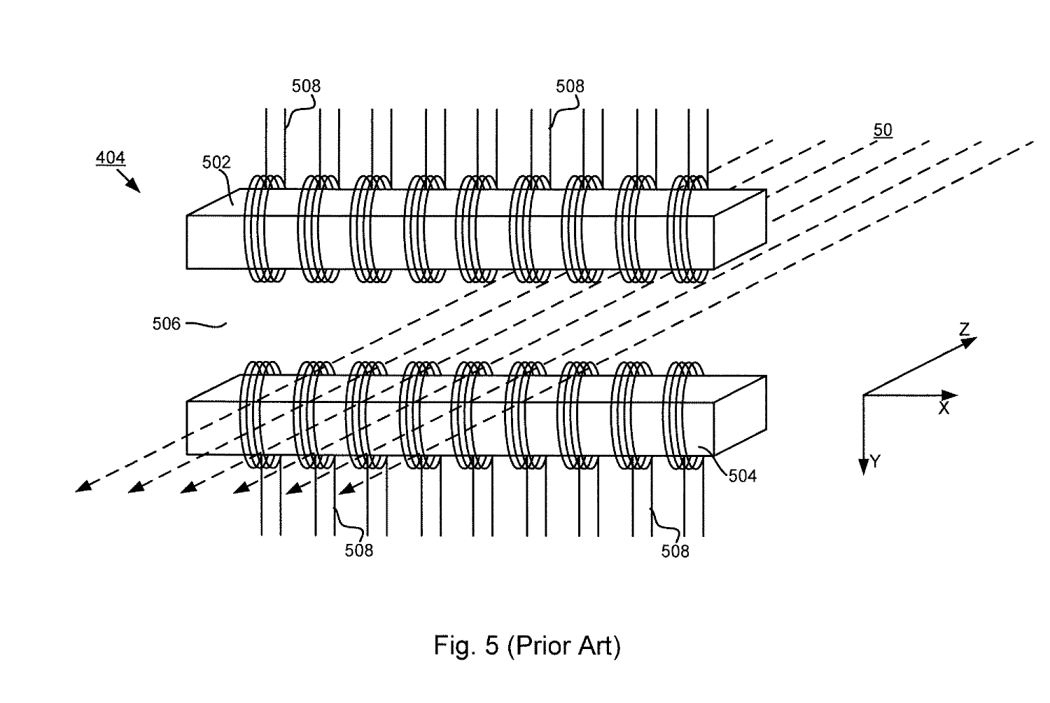

### DETAILED DESCRIPTION OF EXEMPLARY EMBODIMENTS

Embodiments of the present disclosure improve upon the above-described techniques by providing dose uniformity and angle uniformity in an ion beam. In addition, embodiments of the present disclosure provide various scanning high resolution angle profiler (SHRAP) configurations that may provide measuring and controlling ion beam angle and density uniformity in ion implantation operations.

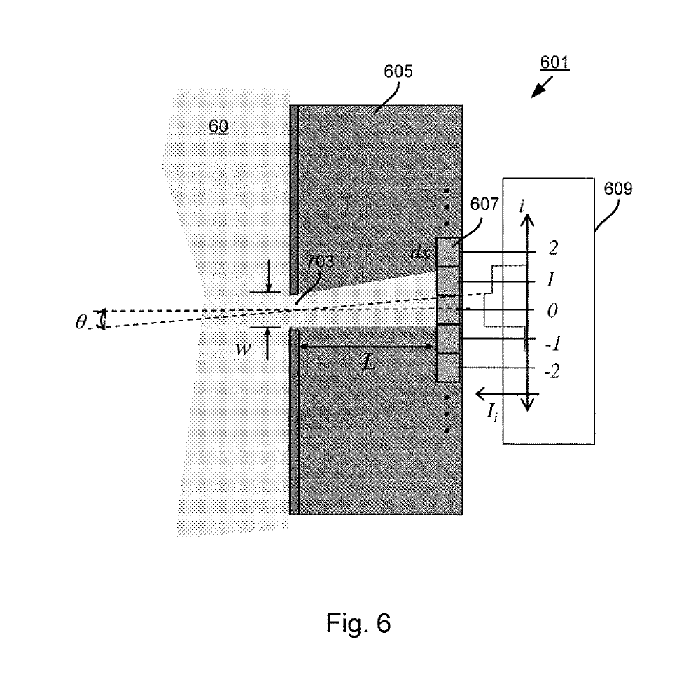

Referring to FIG. 6, a measuring assembly 601 is shown in accordance with an embodiment of the present disclosure. For example, the measuring assembly 601 may be a scanning high resolution angle profiler (SHRAP) having an opening 603 (e.g., an aperture or slit) and a cup 605. In this example, the slit 603 may have a width w to allow ion beam entrance into the cup 605. The cup may have a length L and may include at least two collectors 607 positioned at the rear of the cup 605 (opposite that of the slit 603). The at least two collectors 607 may cover a limited portion of the rear of the cup 605 or the entire width of the rear of the cup 605. Each of the at least two collectors 607 may have a width dx greater than, equal to, or less than the width w of the slit 603, or a combination thereof. When each of the at least one collectors 607 has a width dx lesser than the width w of the slit 603, higher resolution measurements may be provided by the SHRAP 601. Furthermore, minimizing gaps between two or more of the at least one collector 607 may assist in an averaging process interpolation performed at a differential amplifier 609, which in turn also yields high resolution measurements.

The differential amplifier 609 receives signals from the at least one collector 607 and may calculate dose I(x), angle θₓ(x), and/or variance δ²θₓ(x) measurements. Measurement calculations for angle θx(x) and variance δ(θx(x)) may be depicted by the following expressions:

$$θ = \frac{d x}{L} ( \frac{\sum i \cdot {I}_{i}}{\sum {I}_{i}} )$$

$${δ}^{2} θ = \frac{d {x}^{2}}{L} ( \frac{\sum {i}^{2} \cdot {I}_{i}}{\sum {I}_{i}} - {( \frac{\sum i \cdot {I}_{i}}{\sum {I}_{i}} )}^{2} ) ,$$

where θ represents an angle of incidence, dx is a width of the at least one collector 607, and Iᵢ represents a dose current from collector i.

Employing the measuring assembly 601 (e.g., single scanning slit faraday or SHRAP) with at least two collector 607 at the rear of the cup 605 provides several benefits and advantages. For example, when there are a multiplicity of collectors 607, e.g., greater than three (3), ion beam current measurements may provide dose I(x), angle θₓ(x), and a variance δ²θₓ(x), as described above. Furthermore, these measurements may be in high resolution.

Additionally, utilizing a single measuring assembly 601, rather than multiple measuring assemblies, to scan across an ion beam 60, reliable and consistent measurements may be taken of the ion beam 60. For example, a single SHRAP 601 having a multiplicity of collectors at the rear of the cup may be rather complex in design. Replicating the exact complexity of the SHRAP 601 into multiple SHRAPs to scan the ion beam 60 without any trace of variation may not be possible. As a result, utilizing one SHRAP 601 instead of multiple SHRAPS having distinct (even if slight) variations in collector variation may provide such distinct advantages. There are several other important design criteria as well.

For example, the measuring assembly 601 may be compact in size, have an ability to measure both angle and density profiles in high resolution, and be designed for flexible and customizable configurations. With regards to size, embodiments of the present disclosure may provide accurate measurements with approximately one (1) inch of beam length as compared to a “pepperpot” approach, which may require over ten (10) inches of beam length.

With regards to measurement benefits, the fact that the measuring assembly 601 of the present disclosure does not assume zero-emittance in order to yield accurate average angles, measurements may be achieved with great accuracy and in high resolution.

With regards to flexibility, if absolute current measurement is desired, magnetic suppression and other add-on features may also be coupled to the measuring assembly configuration as well. In another embodiment, the measuring assembly 601 may be subdivided into multiple sections. For example, the measuring assembly 601 may be split in both x and y directions to provide a measurement of vertical-beam centering as well as a variation of average horizontal angles with a vertical position. In particular, an upper part of the ion beam 60 may be detected where the upper part of the ion beam 60 may have different horizontal angles than that of a lower part. Other various embodiments may also be provided.

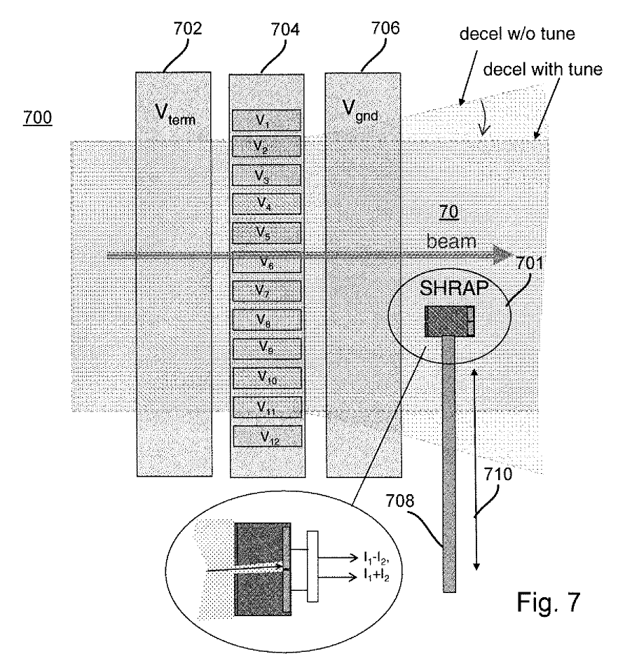

FIG. 7 depicts an electrostatic lens configuration 700 using a scanning high resolution angle profiler (SHRAP) 701 according to an embodiment of the present disclosure. The electrostatic lens configuration 700 may include an entrance electrode 702, a suppression electrode 704, and an exit electrode 706. The suppression electrode 704 may include one or more focusing poles V₁-V₁₂. Although twelve (12) focusing poles are depicted in this example, it should be appreciated that greater or lesser numbers may also be provided.

As discussed above, when a parallel ribbon beam of high current is decelerated at low energy, space charge forces may make it difficult to tune the voltages of one or more focusing poles V₁-V₁₂. However, a measuring assembly, e.g., a scanning high resolution angle profiler (SHRAP) 701, may be positioned immediately after the deceleration lenses on an actuator (e.g. a linear actuator 708) along an actuation path (e.g., linear actuation path 710) that intersects an ion beam 70. Under this particular configuration, one or more of the focusing poles V₁-V₁₂ may be tuned to compensate the various space charge forces fairly accurately.

For instance, the SHRAP 701 may collect beam measurements in the form of response curves (or other similar measurement format) for each of the one or more focusing poles V₁-V₁₂. In one embodiment, the shape of these response curves, for example, may be indicative of lens geometry and/or other various lens features. In another embodiment, as the voltage for any one of these one or more focusing poles V₁-V₁₂ are varied, the entire response curve may change proportionately. Furthermore, by taking a linear combination of these response curves (e.g., over all focusing poles V₁-V₁₂), angle distributions produced by the deceleration lenses 702, 704, 706 may be analyzed. As a result, the response curves may serve as a set of basis functions for the tuning capability of the deceleration lenses 702, 704, 706.

If, however, the SHRAP 701 is some distance d downstream of the deceleration lenses 702, 704, 706, the response functions may be transformed back to the lens, e.g., by using linear transformations x₂=x₁+θ·d and θ(x₂)=θ(x₁), where x₂ represents a horizontal distance of a ray from a center of the ion beam at a downstream position and x₁ represents a horizontal distance of a ray from a center of the ion beam at the lens. Other various embodiments may also be provided.

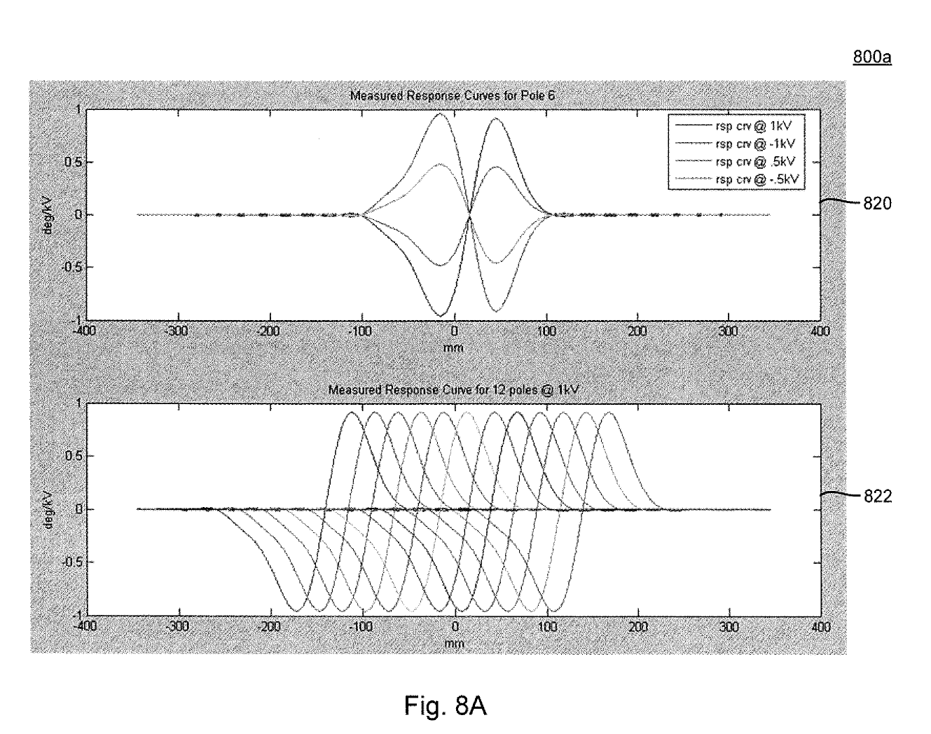

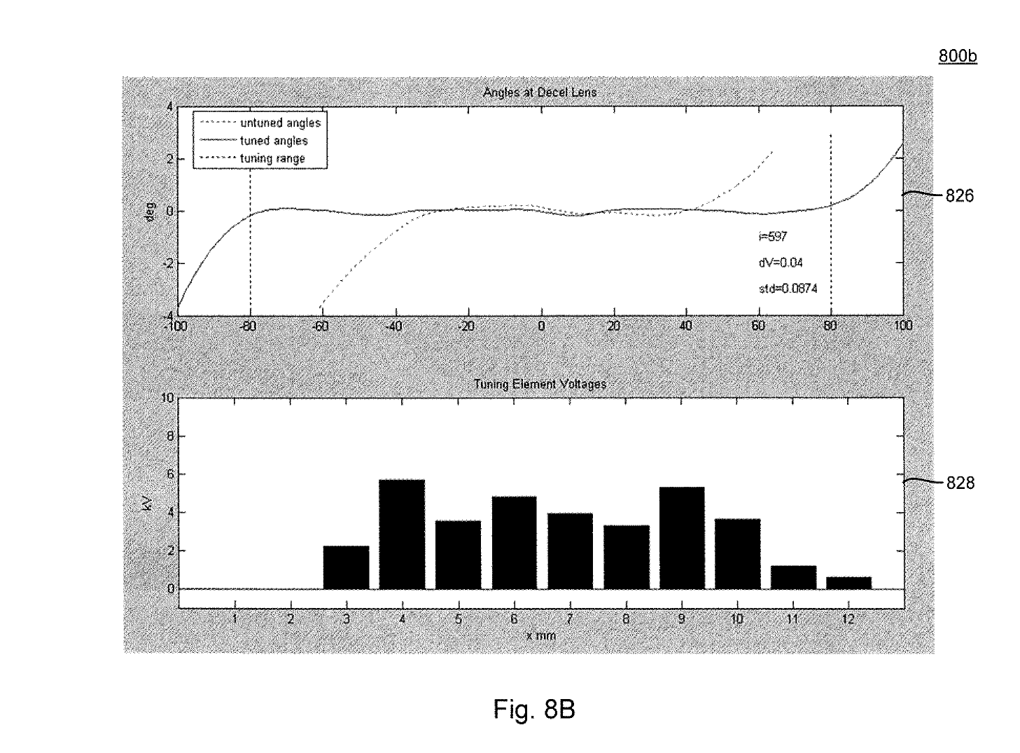

FIG. 8A depicts exemplary screenshots 800a of measurements using a scanning high resolution angle profiler (SHRAP) 801 according to an embodiment of the present disclosure. Here, an exemplary measured response curve 820 for focusing pole V₆ and an exemplary measured response curve 822 for all twelve (12) focusing poles V₁-V₁₂ at 1 keV are depicted.

Referring back to FIG. 7, in addition to collecting beam measurements in the form of response curves, the SHRAP 701 may also measure the angles across the decelerated ion beam 70. In one embodiment, for example, the SHRAP 701 may measure angles without activating any of the focusing poles. Accordingly, basis functions may still be utilized to obtain the set of voltages Vᵢ that minimizes the deviation of angles to a desired profile, e.g., by processing the values through a computer processor (not shown). In one embodiment, the generated profile may be parallel or may be tuned to other focal points. In another embodiment, a multi-dimensional search method, such as gradient, conjugate gradient, or other similar search, may be used. Other various embodiments may also be provided.

FIG. 8B depicts exemplary screenshots 800b of measurements using a scanning high resolution angle profiler (SHRAP) 801 according to an embodiment of the present disclosure. Here, exemplary measured angles 826 at a deceleration lens and exemplary measured voltages 828 for each of the exemplary twelve (12) focusing poles V₁-V₁₂ are depicted.

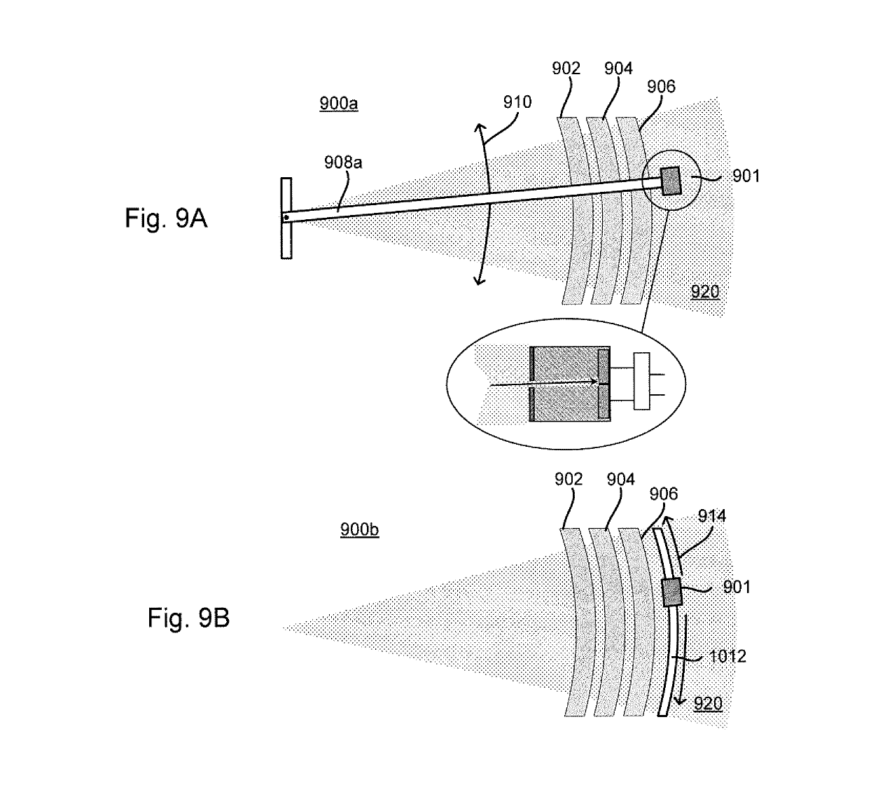

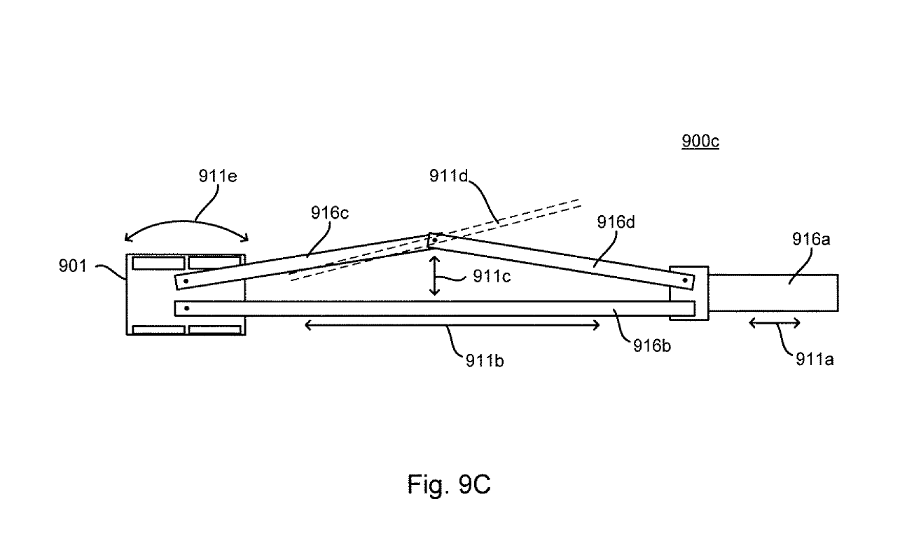

Other ways to maximize the precision of measuring and controlling angle and/or dose uniformity may also be provided. FIG. 9A depicts an exemplary actuation configuration 900a for a scanning high resolution angle profiler (SHRAP) 901 according to an embodiment of the present disclosure. In this example, an expanding ion beam 920 is depicted. Rather than utilizing the linear actuation path 710 as shown in FIG. 7, a SHRAP 901 may be coupled to a pivoting actuator 908 so that the SHRAP 901 may traverse along the ion beam path in an arc-like actuation path 910, as depicted in FIG. 9A. Here, incoming angles of the expanding ion beam 920 may be “zeroed out” via the arc-like actuation path 910. As a result, the SHRAP 901 may therefore measure only the aberrant angles caused by space charge forces arising from a deceleration lens (e.g., an entrance electrode 902, a suppression electrode 904, or an exit electrode 906), which may need to be compensated by the tuning elements to ensure high resolution angle and dose measurements. In one embodiment, the pivoting actuator 908 may be pivoted from the focal point of the ion beam 920. In another embodiment, the arm of the pivoting actuator 908 need not extend totally to the focal point. Instead, the pivoting actuator 908a may pivot from any point to optimize measurement. Other various embodiments may also be provided.

FIG. 9B depicts exemplary actuation configuration 900b for a scanning high resolution angle profiler (SHRAP) 901 according to an embodiment of the present disclosure. Rather than using a pivoting actuator 908 pivoting from the focal point of the ion beam 920, as depicted in FIG. 9A, in this example, a SHRAP 901 may traverse along the ion beam path on a curved rail 912 in an arc-like actuation path 914. The curved rail 912 may be above or below the SHRAP 901. Other various embodiments may also be provided.

FIG. 9C depicts another exemplary actuation configuration 1000c for a scanning high resolution angle profiler (SHRAP) 901 according to an embodiment of the present disclosure. In this example, movement of a SHRAP 901 along an actuation path may be more refined by including two or more actuation components. In one embodiment, a SHRAP 901 may be attached to an actuator 916 having a first straight linear actuator 1016a that moves along a first actuation path 911a, a second straight linear actuator 916b that coordinates with a first pivoting actuator 916c and a second pivoting actuator 916d to guide the SHRAP 901 along second actuation path 911b and a third actuation path 911c. The second straight linear actuator 916b may also coordinate with the first pivoting actuator 916c and the second pivoting actuator 916d to move along an angle pivot 911d for greater fluidity. Combining these components may allow the SHRAP 901 to move in various geometric actuation paths to maximize accuracy in measuring and controlling dose and/or angle uniformity. In one embodiment, In another embodiment, the SHRAP 901 may be attached to the second straight linear actuator 916b and the first pivoting actuator 916c at one or more pivot points, as depicted in FIG. 9C, so that the SHRAP 901 may rotate along its own axis in rotating actuation path 911e. As a result, this attachment configuration may provide more flexibility and therefore accuracy in measuring the ion beam 920.

It should be appreciated that while the actuation configuration 900c, as depicted in FIG. 9C, may provide more fine-tuned measurements, additional parts and/or actuation components may be required. Furthermore, greater electronic sensitivity in controlling these components may be required. Other various embodiments may also be provided.

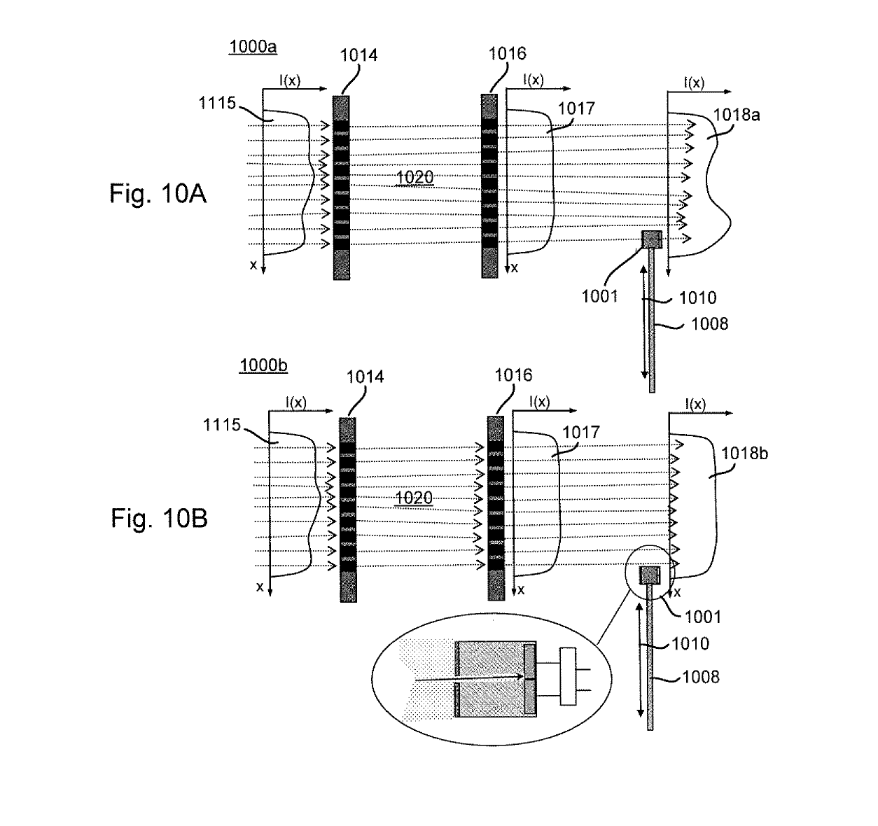

FIGS. 10A-10B depict exemplary tuning configurations 1000a and 1000b using a scanning high resolution angle profiler (SHRAP) 1001 according to an embodiment of the present disclosure. In these examples, two sets of tuning elements, e.g., a first tuning element 1014 and a second tuning element 1016, may be used for correcting ion beam density and/or angles. In one embodiment, the first tuning element 1014 may be placed at a deceleration lens. In this example, the first tuning element 1014 may include either electrostatic poles, magnetic multipoles, or other tuning features. In another embodiment, the first tuning element 1014 may be independent of any deceleration lens. In this example, magnetic poles may be utilized in the first tuning element 1014 in order to avoid large space charge effects.

The second tuning element 1016 may also be electrostatic (e.g., within another electrostatic lens) or magnetic. As depicted in FIGS. 10A and 10B, the second tuning element 1016 may be placed downstream of the first tuning element 1014 before a wafer plane (not shown). In this example, the SHRAP 1001 may be attached to a linear actuator 1008 so that the SHRAP may scan an ion beam 1020 along a linear actuation path 1010. By positioning the SHRAP 1001 after the second tuning element 1016, both uniform density profile and uniform angles may be provided at the wafer. Although the SHRAP 1001 may be placed immediately after the second tuning element, as depicted in FIGS. 10A and 10B, it should be appreciated that the SHRAP 1001 may also be placed further downstream. Other various embodiments may also be provided.

In order to provide both a uniform density profile and uniform angles at the wafer, the first tuning element 1014 may be tuned so that a density profile 1017 is uniform at the second tuning element 1016. As shown in FIG. 10A, this may be achieved by using the profile and angles measured by the downstream SHRAP 1001 and projecting the profile back to the second tuning element 1016 by linear transformation. By measuring response curves (or other similar formats) for the individual focusing poles of the first tuning element 1014, the measurements may be used to obtain the correct settings to achieve uniformity at the second tuning element 1016. As a result, the first tuning element 1014 may be tuned to produce a uniform profile 1017 at the second tuning element 1016 as projected back using the profile and angles measured by the SHRAP 1001. It should be appreciated that a combined dose and angle profile 101a may not be fully uniform after tuning the first tuning element 1014.

It should also be appreciated that determining settings for uniformity may require several iterations or calculations. Moreover, in order to provide angle uniformity, the second tuning element 1016 may be required to have the capability to compensate for the angles received from the first tuning element 1014. For example, the angles may be compensated by the second tuning element 1016 as a function of x.

As shown in FIG. 10B, the second tuning element 1016 may also be tuned so that the angles and profiles are uniform at the SHRAP 1001 (and therefore the second tuning element 1016). Accordingly, the second tuning element 1016 may be tuned to produce both uniform profile and angles 1018b at the SHRAP 1001 and wafer. Angle and density uniformity may be achieved by collecting response curves (or other similar formats) for each individual focusing pole and measuring angles across the decelerated ion beam as discussed above with reference to the electrostatic configurations depicted in FIGS. 7-8B.

It should be appreciated that while this approach may separate the roles of the first tuning element 1014 and the second tuning element 1016, e.g., the tuning of density at the first tuning element 1014 and angle uniformity at the second tuning element 1016, such a technique may facilitate corrections. For example, adjustments to an angle profile may be independent to adjustments to that of a density/dose profile, making it easier to tune as compared to tuning all poles together to achieve a common (combined) goal of both angles and density uniformity.

It should be appreciated that while embodiments of the present disclosure mainly electrostatic configurations (e.g., deceleration lenses), other implementations utilizing magnetic configurations, such as magnetic coils, correctors, or other magnetic tuning elements, may similar apply.

It should be also appreciated that while embodiments of the present disclosure are directed to a scanning high resolution angle profiler (SHRAP) for measuring and controlling angle and beam uniformity, other implementations may be provided as well. For example, the disclosed techniques for utilizing a SHRAP for measuring and controlling angle and beam uniformity may apply to other various ion implantation systems that use electric and/or magnetic deflection or any other beam tuning systems.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure can be beneficially implemented in any number of environments for any number of purposes. Accordingly, the claims set forth below should be construed in view of the full breadth and spirit of the present disclosure as described herein.

1. An apparatus for measuring and controlling ion beam uniformity, the apparatus comprising:
a measuring assembly comprising an opening, a cup, and at least two collectors at the rear of the cup; and
an actuator to move the measuring assembly along an actuation path to scan an ion beam to measure and control ion beam uniformity.

2. The apparatus of claim 1, wherein the ion beam uniformity comprises at least one of angle uniformity and dose uniformity.

3. The apparatus of claim 1, wherein the at least one collector has a width that is equal to or less than the width of the opening.

4. The apparatus of claim 1, wherein the measuring assembly scans across an ion beam along an actuation path to collect ion beam information.

5. The apparatus of claim 1, wherein the actuator comprises one of a single straight linear actuator, a pivoting actuator, a curved rail actuator, or a combination thereof.

6. The apparatus of claim 1, wherein the actuation path is at least one of a curved actuation path and a straight actuation path.

7. The apparatus of claim 1, wherein the measuring assembly is rotatable about an axis at a point where the measuring assembly is connected to the actuator.

8. The apparatus of claim 1, further comprising a differential amplifier coupled to the at least two collectors of the measuring assembly.

9. The apparatus of claim 8, wherein the differential amplifier determines ion beam angle uniformity based on ion beam measurements by the at least two collectors.

10. The apparatus of claim 1, further comprising one or more tuning elements for tuning ion beam uniformity.

11. The apparatus of claim 10, wherein the one or more tuning elements are at least one of electrostatic tuning elements and magnetic tuning elements.

12. A method for providing ion beam uniformity, the method comprising:
tuning a first tuning element, based on a first set of ion beam information collected at a measuring assembly, to provide dose uniformity at a second tuning element, downstream from the first tuning element; and
tuning the second tuning element, based on a second set of ion beam information collected at the measuring assembly, to provide dose and angle uniformity at a wafer.

13. The method of claim 12, wherein the ion beam information comprises information relating to at least one of angle uniformity and dose uniformity.

14. The method of claim 12, wherein the measuring assembly scans across an ion beam along an actuation path to collect ion beam information.

15. The method of claim 14, wherein the actuation path is at least one of a curved actuation path and a straight actuation path.

16. The method of claim 12, wherein tuning the first tuning element further comprises generating at least a first response curve based on the first set of ion beam information, and wherein tuning the second tuning element further comprises generating at least a second response curve based on the second set of ion beam information.

17. The method of claim 16, wherein tuning the first tuning element and tuning the second tuning element comprises adjusting voltage to correct ion beam deviations based on the response curves.

18. The method of claim 12, wherein the first tuning element and the second element are adjusted individually and independently.

19. The method of claim 12, wherein the measuring assembly is downstream from both the first and second tuning elements.
